(19) United States
(12) Patent Application Publication
(10) Pub. No.: US 2014/0003159 A1
(43) Pub. Date: Jan. 2, 2014

(54) NONVOLATILE MEMORY DEVICE, OPERATING METHOD THEREOF, AND DATA STORAGE DEVICE HAVING THE SAME

(71) Applicant: SK HYNIX INC., Icheon-si (KR)

(72) Inventor: Sung Hyun JUNG, Icheon-si (KR)

(73) Assignee: SK HYNIX INC., Icheon-si (KR)

(21) Appl. No.: 13/709,337

(22) Filed: Dec. 10, 2012

(30) Foreign Application Priority Data
Jun. 28, 2012 (KR) 10-2012-0069816

(51) Int. Cl. G11C 16/04

(52) U.S. Cl. CPC G11C 16/04
USPC 365/185.29

(57) ABSTRACT

A nonvolatile memory device including a plurality of memory cells arranged at a region where word lines and bit lines cross each other, a control logic configured to control an erase operation for the memory cells, and a voltage generator configured to apply an erase voltage to the memory cells according to control of the control logic, and collect the applied erase voltage to reuse.

### CROSS-REFERENCES TO RELATED APPLICATION

The present application claims priority under 35 U.S.C. §119(a) to Korean application number 10-2012-0069816, filed on Jun. 28, 2012, in the Korean Intellectual Property Office, which is incorporated herein by reference in its entirety.

### BACKGROUND

1. Technical Field

The present invention generally relates to a semiconductor memory device, and more particularly, to a nonvolatile memory device, an operating method thereof, and a data storage device having the same.

2. Related Art

In general, a semiconductor memory device is classified into a volatile memory device and a nonvolatile memory device. The volatile memory device loses data stored therein when power supply is cut off, but the nonvolatile memory device maintains data stored therein even though power supply is cut off. The nonvolatile memory device may include various types of memory cells.

The nonvolatile memory device may be divided into a flash memory device, a ferroelectric RAM (FRAM) using a ferroelectric capacitor, a magnetic RAM (MRAM) using a tunneling magneto-resistive (TMR) layer, a phase change memory device using chalcogenide alloys and the like, depending on the structures of memory cells.

Among the nonvolatile memory devices, the flash memory device is roughly divided into a NOR flash memory device and a NAND flash memory device, depending on the connection state between memory cells and a bit line. The NOR flash memory device has a structure in which two or more memory cell transistors are connected in parallel to one bit line. Therefore, the NOR flash memory device has an excellent random access time characteristic. On the other hand, the NAND flash memory device has a structure in which two or more memory cell transistors are connected in series to one bit line. Such a structure is referred to as a cell string, and one bit line contact is required per one cell string. Therefore, the NAND flash memory device has an excellent characteristic in terms of integration degree.

An erase operation of the flash memory device is performed through Fowler-Nordheim (F-N) tunneling. That is, the erase operation of the flash memory device is performed by applying a high voltage to a well having a memory cell formed therein and discharging charges stored in the memory cell. For the erase operation, a high voltage is used. The flash memory device not only may require a relatively long time to generate a high voltage used for the erase operation, but also may consume large power.

### SUMMARY

A nonvolatile memory device which reuses a collected voltage, an operating method thereof, and a data storage device having the same are described herein.

In an embodiment, a nonvolatile memory device includes: a plurality of memory cells arranged at a region where word lines and bit lines cross each other; a control logic configured to control an erase operation for the memory cells; and a voltage generator configured to apply an erase voltage to the memory cells according to control of the control logic, and collect the applied erase voltage to reuse.

In an embodiment, an operating method of a nonvolatile memory device includes the steps of: applying a first erase voltage to memory cells; collecting the first erase voltage; and generating a second erase voltage larger than the first erase voltage, using the collected first erase voltage.

In an embodiment, a data storage device includes: a nonvolatile memory device; and a controller configured to control the nonvolatile memory device, wherein the nonvolatile memory device includes: a plurality of memory cells arranged at a region where word lines and bit lines cross each other; a control logic configured to control an erase operation for the memory cells; and a voltage generator configured to apply an erase voltage to the memory cells according to control of the control logic, and collect the applied erase voltage to reuse.

### BRIEF DESCRIPTION OF THE DRAWINGS

Features, aspects, and embodiments are described in conjunction with the attached drawings, in which:

FIG. 1 is a block diagram illustrating a nonvolatile memory device according to an embodiment;

FIG. 2 is a flow chart showing an operating method of the nonvolatile memory device according to an embodiment;

FIG. 3 is a cross-sectional view for explaining a bias condition of a memory cell which operates according to the flow chart of FIG. 2;

FIG. 4 is a block diagram illustrating a voltage generator of the nonvolatile memory device according to an embodiment;

FIG. 5 is a block diagram illustrating a data processing system including the nonvolatile memory device according to an embodiment;

FIG. 6 illustrates a memory card including a nonvolatile memory device according to an embodiment;

FIG. 7 is a block diagram illustrating the internal configuration of the memory card illustrated in FIG. 8 and the connection relation between the memory card and a host;

FIG. 8 is a block diagram illustrating an SSD including the nonvolatile memory device according to an embodiment;

FIG. 9 is a block diagram illustrating an SSD controller illustrated in FIG. 8; and

FIG. 10 is a block diagram illustrating a computer system in which a data storage device having the nonvolatile memory device according to an embodiment is mounted.

### DETAILED DESCRIPTION

Hereinafter, a nonvolatile memory device, an operating method thereof, and a data storage device having the same according to various embodiments will be described below with reference to the accompanying drawings through the various embodiments.

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

The drawings are not necessarily to scale and in some instances, proportions may have been exaggerated in order to clearly illustrate features of the embodiments. In this specification, specific terms have been used. The terms are used to describe the present invention, and are not used to qualify the sense or limit the scope of the present invention.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include a plural form as long as it is not specifically mentioned in a sentence. Furthermore, ‘include/comprise’ or ‘including/comprising’ used in the specification represents that one or more components, steps, operations, and elements exists or are added.

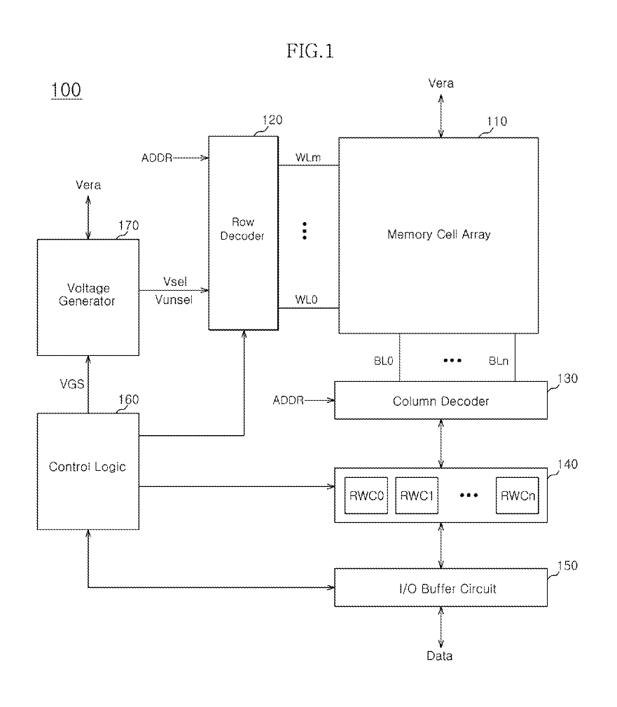

FIG. 1 is a block diagram illustrating a nonvolatile memory device according to an embodiment. Referring to FIG. 1, the nonvolatile memory device 100 includes a memory cell array 110, a row decoder 120, a column decoder 130, a data read/write circuit 140, an input/output (I/O) buffer circuit 150, a control logic 160, and a voltage generator 170.

The memory cell array 110 includes a plurality of memory cells arranged at the respective intersections between bit lines BL0 to BLn and word lines WL0 to WLm. Each of the memory cells may store one-bit data. Such a memory cell is referred to as a single level cell (SLC). The SLC is programmed in such a manner as to have a threshold voltage corresponding to an erase state and one program state. As another example, each of the memory cells may store two or more-bit data. Such a memory cell is referred to as a multi-level cell (MLC). The MLC is programmed in such a manner as to have a threshold voltage corresponding to an erase state and any one of a plurality of program states. The memory cell array 110 may be implemented to have a single-layer array structure or multi-layer array structure. The single-layer array structure is referred to as a 2D array structure, and the multi-layer array structure is referred to as a 3D array structure.

The row decoder 120 operates according to the control of the control logic 160. The row decoder 120 is connected to the memory cell array 110 through a plurality of word lines WL0 to WLm. The row decoder 120 is configured to decode an address ADDR inputted from outside. The row decoder 120 is configured to selectively drive the word lines WL0 to WLm according to the decoding result. For example, the row decoder 120 may provide a selected voltage Vsel to a selected word line, and provide an unselected voltage Vunsel to an unselected word line.

The column decoder 130 operates according to the control of the control logic 160. The column decoder 130 is connected to the memory cell array 110 through bit lines BL0 to BLn. The column decoder 130 is configured to decode the address ADDR. The column decoder 130 is configured to sequentially connect the bit lines BL0 to BLn to the data read/write circuit 140 according to the decoding result.

The data read/write circuit 140 operates according to the control of the control logic 160. The data read/write circuit 140 is configured to operate as a write driver or sense amplifier depending on an operation mode. For example, the data read/write circuit 140 is configured to store data inputted through the I/O buffer circuit 150 in a memory cell of the memory cell array 110 during a program operation. For another example, the data read/write circuit 140 is configured to output data read from a memory cell of the memory cell array 110 to the I/O buffer circuit 150 during a read operation. The data read/write circuit 140 may include a plurality of data read/write circuits RWC0 to RWCn corresponding to the respective bit lines BL0 to BLn (or bit line pairs). For this reason, the bit lines BL0 to BLn (or bit line pairs) may be selected or controlled by the corresponding data read/write circuits RWC0 to RWCn, respectively.

The I/O buffer circuit 150 is configured to receive data (Data) from an external device (for example, a memory controller, a memory interface, a host device or the like) or output data to the external device. For this operation, the I/O output buffer circuit 150 may include a data latch circuit (not illustrated) and an output driving circuit (not illustrated).

The control logic 160 is configured to control overall operations of the nonvolatile memory device 100 in response to a control signal provided from the external device. For example, the control logic 160 may control read, program (or write), and erase operations of the nonvolatile memory device 100. For this operation, the control logic 160 controls the voltage generator 170 to apply a voltage required during operation to the respective components.

The voltage generator 170 is configured to generate a voltage according to the control of the control logic 160. That is, the voltage generator 170 is configured to generate the voltage required during operation, in response to a voltage generation control signal VGS provided from the control logic 160.

The voltage generator 170 according to an embodiment is configured to collect an erase voltage Vera applied during an erase operation and reuse the collected erase voltage Vera. For example, when negative charges stored in a well having the memory cell array 110 formed therein, that is, negative charges stored by the erase voltage Vera applied to the well are discharged during the erase operation, the voltage generator 170 stores the discharged negative charges. The voltage generator 170 is configured to generate an erase voltage Vera which is to be used during the next erase operation, using the voltage generated by the stored negative charges.

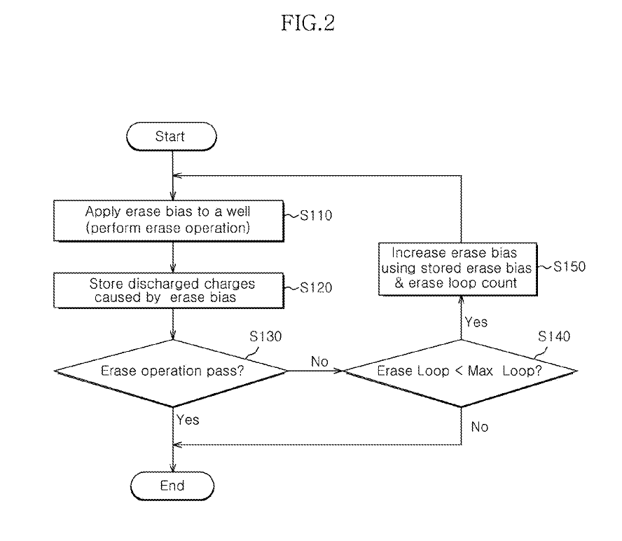

FIG. 2 is a flow chart showing an operating method of the nonvolatile memory device according to an embodiment. The nonvolatile memory device 100 of FIG. 1 performs an erase operation through an incremental step pulse erase (ISPE) scheme that gradually increases an erase voltage from a low voltage to a high voltage.

At step S110 (Apply erase bias to a well (perform erase operation)), a first erase voltage is applied to a semiconductor substrate having the memory cell array 110 formed therein, that is, a well area. Simultaneously, when a memory cell to be erased is selected according to a bias condition applied to memory cells of the memory cell array 110, an erase operation is performed.

At step S120 (Store discharged charges caused by erase bias) when negative charges stored in the well are discharged by the applied erase voltage, the discharged negative charges are stored. After the negative charges are stored, a discharge operation using a ground path may be additionally performed to sufficiently discharge the well.

At step S130 (Erase operation pass?), a threshold voltage of the erased memory cell is verified to determine whether the erase operation is a pass or not (i.e., Yes or No). That is, the erase verification operation is performed on the memory cell in which the erase operation was performed. When it is determined that the erase operation is a pass, the erase operation is normally ended. However, when it is determined that the erase operation is a fail, the procedure proceeds to step S140.

At step S140 (Erase Loop<Max Loop?), whether or not the number of operation loops of the erase operation is smaller than the maximum loop number is determined (i.e., Yes or No). When the operation loop number of the erase operation corresponds to the maximum loop number (i.e., No), the erase operation is abnormally ended (i.e., End). However, when the operation loop number of the erase operation is smaller than the maximum loop number (i.e., Yes), the procedure proceeds to step S150.

At step S150 (Increase erase bias using stored erase bias & erase loop count), the erase voltage is increased by a step voltage (for example, a preset increment). At this time, the voltage generated by the charges stored at step S120 is used. Furthermore, an operation of applying the increased erase voltage to the selected memory cell and then performing erase verification is repetitively performed until the selected memory cell is erased.

According to an embodiment, a voltage stored when an erase voltage applied during a previous erase operation is discharged may be used to generate an erase voltage which is to be used during a next erase operation. As a result, the time required for generating the erase voltage may be saved, and the power consumption may be reduced.

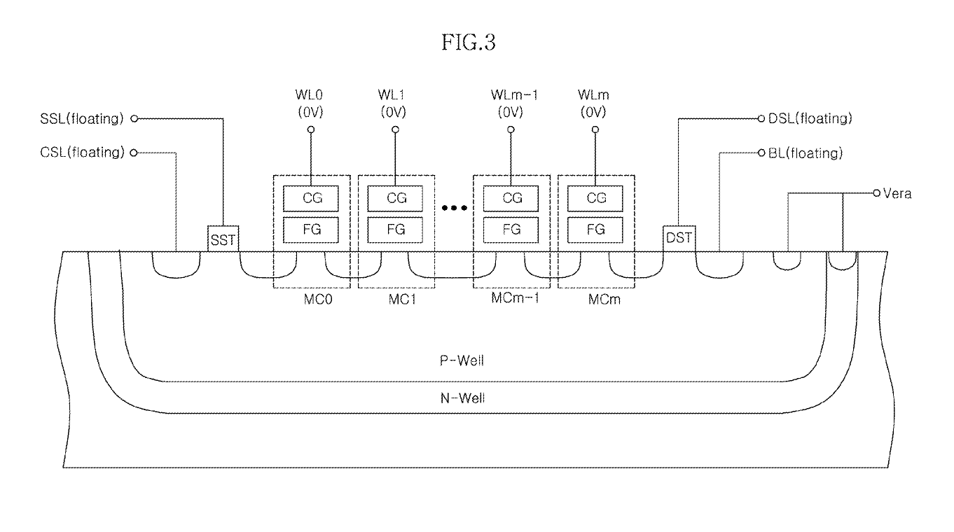

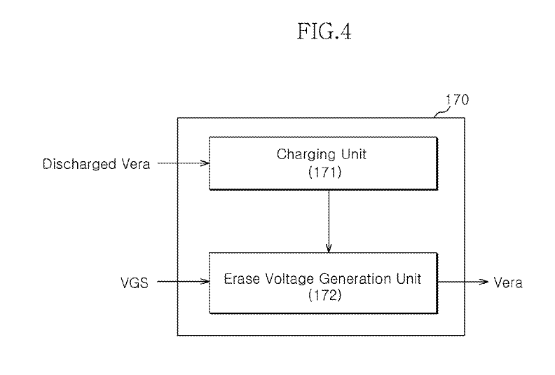

FIG. 3 is a cross-sectional view for explaining a bias condition of a memory cell which operates according to the flow chart of FIG. 2. FIG. 4 is a block diagram illustrating the voltage generator of the nonvolatile memory device according to an embodiment.

The memory cell array 110 of FIG. 1 includes a plurality of memory blocks. The memory block is an operation unit for performing an erase operation. The memory block includes a plurality of memory cell strings connected to a plurality of bit lines, respectively. FIG. 3 illustrates one memory cell string, for convenience of description.

The memory cell string includes a plurality of memory cells MC0 to MCm and select transistors DST and SST (i.e., drain select transistors and source select transistors), which are connected between a bit line BL (not illustrated) and a common source line CSL (not illustrated). For example, the memory cell string has a structure in which the drain select transistor DST connected to a drain select line DSL, the plurality of memory cells MC0 to MCm connected to a plurality of word lines WL0 to WLm, respectively, and the source select transistor SST connected to a source select line SSL are connected in series. Additionally, the memory cells MC0 to MCm may include floating gates FG and control gates CG.

As described above, the nonvolatile memory device 100 may erase a selected memory block through the ISPE scheme. The erase operation will be described in more detail as follows.

First, a first erase voltage Vera1 (i.e. erase voltage Vera) for erasing a memory block is applied to a semiconductor substrate, that is, a well area having the memory block formed therein. The well area includes a P-well and an N-well. The first erase voltage Vera1 is generated and applied by an erase voltage generation unit 172 of the voltage generator 170, based on a voltage generation control signal VGS. In order to select the memory block to be erased among memory blocks formed in the well area, a bit line BL, a drain select line DSL, a source select line SSL, and a common source line CSL of the memory block to be erased are set in a floating state (i.e., floating). Furthermore, a ground voltage of 0V is applied to word lines WL0 to WLm of the memory block to be erased.

When charges stored in floating gates FG of memory cells included in the selected memory block are discharged to the well area by the first erase voltage Vera1 applied during a predetermined time, that is, when the selected memory block is erased by F-N tunneling to discharge the stored charges to the well area, the application of the first erase voltage Vera1 is stopped. Furthermore, the charges stored in the well area are discharged by the first erase voltage Vera1. At this time, the discharged charges are provided to a charging unit 171 of the voltage generator 170. That is, the charging unit 171 collects the charges which are stored in the well area and then discharged by the first erase voltage Vera1, and stores the discharged charges (i.e., Discharged Vera). Although not illustrated, the charging unit 171 may include one or more capacitors.

Then, erase verification is performed on the memory block in which the erase operation was performed by the application of the first erase voltage Vera1. As the erase verification result, when it is determined that the selected memory block was not erased, a second erase voltage Vera2 higher than the first erase voltage Vera1 is applied to the well area. For example, the second erase voltage Vera2 increased by a step voltage (for example, a preset increment) from the first erase voltage Vera1 is applied to the well area. The second erase voltage Vera2 (i.e., Vera) is generated by the erase voltage generation unit 172 based on the voltage generation control signal VGS. At this time, the voltage generated by the charges stored in the charging unit 171 is used. The erase loop of applying the second erase voltage Vera2 to erase the selected memory block is repeated.

In this way, the operation of applying the erase voltage and performing erase verification until the selected memory block is erased is repetitively performed within the maximum erase loop number.

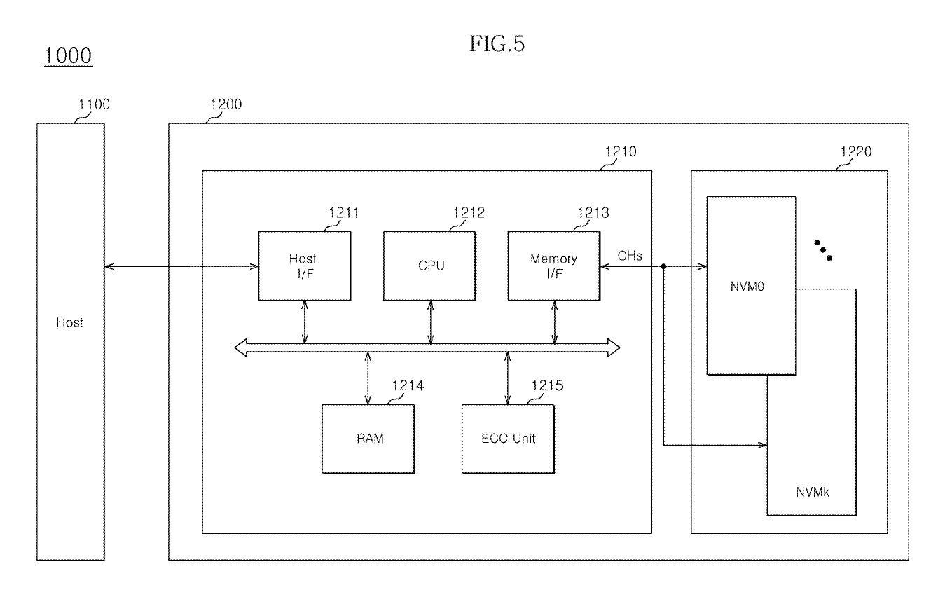

FIG. 5 is a block diagram illustrating a data processing system including the nonvolatile memory device according to an embodiment. Referring to FIG. 5, the data processing system 1000 includes a host 1100 and a data storage device 1200. The data storage device 1200 includes a controller 1210 and a data storage medium 1220. The data storage device 1200 may be connected to the host 1100 such as a desktop computer, a notebook computer, a digital camera, a mobile phone, an MP3 player, a game machine or the like. The data storage device 1200 is also referred to as a memory system.

The controller 1210 is coupled to the host 1100 and the data storage medium 1220. The controller 1210 is configured to access the data storage medium 1220 (i.e., by way of channels CHs) in response to a request from the host 1100. For example, the controller 1210 is configured to control a read, program, or erase operation of the data storage medium 1220. The controller 1210 is configured to drive firmware for controlling the data storage medium 1220.

The controller 1210 may include well-known components such as a host interface 1211, a central processing unit (CPU) 1212, a memory interface 1213, a RAM 1214, and an error correction code (ECC) unit 1215.

The CPU 1212 is configured to control overall operations of the controller 1210 in response to a request of the host. The RAM 1214 may be used as a working memory of the CPU 1212. The RAM 1214 may temporarily store data read from the data storage medium 1220 or data provided from the host 1100.

The host interface 1211 is configured to interface the host 1100 and the controller 1210. For example, the host interface 1211 may be configured to communicate with the host 1100 through one of a USB (Universal Serial Bus) protocol, a MMC (Multimedia Card) protocol, a PCI (Peripheral Component Interconnection) protocol, a PCI-E (PCI-Express) protocol, a PATA (Parallel Advanced Technology Attachment) protocol, a SATA (Serial ATA) protocol, an SCSI (Small Computer System Interface) protocol, SAS(Serial SCSI), and an IDE (Integrated Drive Electronics) protocol.

The memory interface 1213 is configured to interface the controller 1210 and the data storage medium 1220. The memory interface 1213 is configured to provide a command and an address to the data storage medium 1220. Furthermore, the memory interface 1213 is configured to exchange data with the data storage medium 1220.

The data storage medium 1220 may be configured as the nonvolatile memory device 100 of FIG. 1 according to an embodiment. The data storage medium 1220 may include a plurality of nonvolatile memory devices NVM0 to NVMk. As the data storage medium 1220 is configured as the nonvolatile memory device 100 according to an embodiment, the operation speed of the data storage device 1200 may be increased, and the power consumption may be reduced.

The ECC unit 1215 is configured to detect an error of the data read from the data storage medium 1220. Furthermore, the ECC unit 1215 is configured to correct the detected error, when the detected error falls within a correction range. Additionally, the ECC unit 1215 may be provided inside or outside the controller 1210 depending on the memory system 1000.

The controller 1210 and the data storage medium 1220 may be integrated to form a solid state drive (SSD).

As another example, the controller 1210 and the data storage medium 1220 may be integrated into one semiconductor device to form a memory card. For example, the controller 1210 and the data storage medium 1220 may be integrated into one semiconductor device to form a PCMCIA (personal computer memory card international association) card, a CF (compact flash) card, a smart media card, a memory stick, a multi-media card (MMC, RS-MMC, or MMC-micro), an SD (secure digital) card (SD, Mini-SD, or Micro-SD), or a UFS (universal flash storage) card.

As another example, the controller 1210 or the data storage medium 1220 may be mounted as various types of packages. For example, the controller 1210 or the data storage medium 1220 may be packaged and mounted according to various methods such as POP (package on package), ball grid arrays (BGAs), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat package (MQFP), thin quad flat package (TQFP), small outline IC (SOIC), shrink small outline package (SSOP), thin small outline package (TSOP), thin quad flat package (TQFP), system in package (SIP), multi chip package (MCP), wafer-level fabricated package (WFP), and wafer-level processed stack package (WSP).

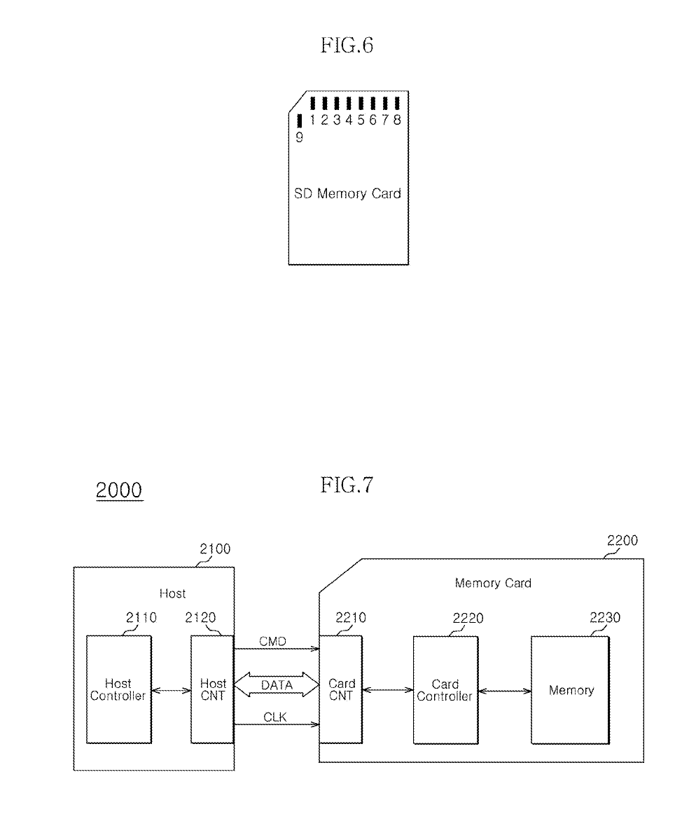

FIG. 6 illustrates a memory card including the nonvolatile memory device according to an embodiment. FIG. 6 illustrates the exterior of an SD (secure digital) card among memory cards.

Referring to FIG. 6, the SD card includes one command pin (for example, second pin), one clock pin (for example, fifth pin), four data pins (for example, first, seventh, eighth, and ninth pins), and three power supply pins (for example, third, fourth, and sixth pins).

Through the command pin (second pin), a command and a response signal are transferred. In general, the command is transmitted to the SD card from a host, and the response signal is transmitted to the host from the SD card.

The data pins (first, seventh, eighth, and ninth pins) are divided into receive (Rx) pins for receiving data transmitted from the host and transmit (Tx) pins for transmitting data to the host. The Rx pins and the Tx pins, respectively, form a pair to transmit differential signals.

The SD card includes the nonvolatile memory device 100 of FIG. 1 according to an embodiment and a controller for controlling the nonvolatile memory device. The controller included in the SD card may have the same configuration and function as the controller 1210 described with reference to FIG. 5.

FIG. 7 is a block diagram illustrating the internal configuration of the memory card illustrated in FIG. 6 and the connection relation between the memory card and a host. Referring to FIG. 7, the data processing system 2000 includes a host 2100 and a memory card 2200. The host 2100 includes a host controller 2110 and a host connection unit 2120 (i.e. Card CNT). The memory card 2200 includes a card connection unit 2210, a card controller 2220, and a memory device 2230.

The host connection unit 2120 and the card connection unit 2210 include a plurality of pins. The pins may include a command pin, a clock pin, a data pin, and a power supply pin. The number of pins may differ depending on the type of the memory card 2200.

The host 2100 stores data in the memory card 2200 or reads data stored in the memory card 2200.

The host controller 2110 transmits a write command CMD, a clock signal CLK generated from a clock generator (not illustrated) inside the host 2100, and data DATA to the memory card 2200 through the host connection unit 2120. The card controller 2220 operates in response to the write command received through the card connection unit 2210. The card controller 2220 stores the received data DATA in the memory device 2230, using a clock signal generated from a clock generator (not illustrated) inside the card controller 2220, according to the received clock signal CLK.

The host controller 2110 transmits a read command CMD and the clock signal CLK generated from the clock generator inside the host device 2100 to the memory card 2200 through the host connection unit 2120. The card controller 2220 operates in response to the read command received through the card connection unit 2210. The card controller 2220 reads data from the memory device 2230 using the clock signal generated from the clock generator inside the card controller 2220, according to the received clock signal CLK, and transmits the read data to the host controller 2110.

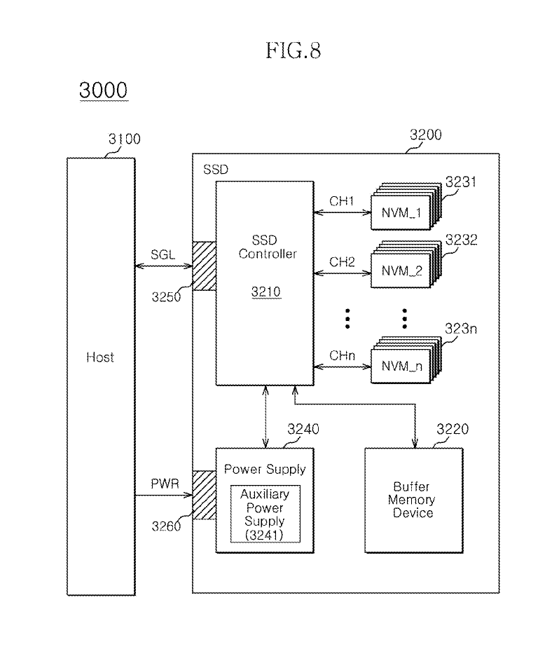

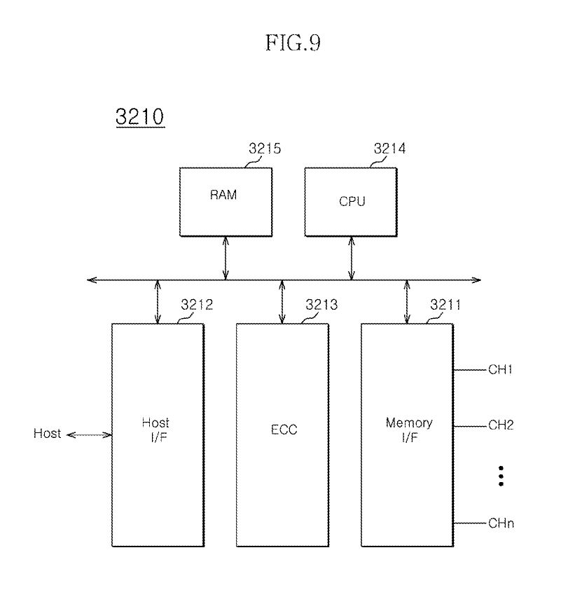

FIG. 8 is a block diagram illustrating an SSD including the nonvolatile memory device according to an embodiment. Referring to FIG. 8, a data processing system 3000 includes a host 3100 and an SSD 3200.

The SSD 3200 includes an SSD controller 3210, a buffer memory device 3220, a plurality of nonvolatile memory devices 3231 to 323n, a power supply 3240, a signal connector 3250, and a power connector 3260.

The SSD 3200 operates in response to a request of the host device 3100. That is, the SSD controller 3210 is configured to access the nonvolatile memory devices 3231 to 323n in response to a request from the host 3100. For example, the SSD controller 3210 is configured to control read, program, and erase operations of the nonvolatile memory devices 3231 to 323n.

The buffer memory device 3220 is configured to temporarily store data which are to be stored in the nonvolatile memory devices 3231 to 323n. Furthermore, the buffer memory device 3220 is configured to temporarily store data read from the nonvolatile memory devices 3231 to 323n. The data temporarily stored in the buffer memory device 3220 are transmitted to the host 3100 or the nonvolatile memory devices 3231 to 323n, according to the control of the SSD controller 3210.

The nonvolatile memory devices 3231 to 323n are used as storage media of the SSD 3200. Each of the nonvolatile memory devices 3231 to 323n may include the nonvolatile memory device 100 of FIG. 1 according to an embodiment. Therefore, the operation speed of the SSD 3200 may be increased, and the power consumption may be reduced.

The respective nonvolatile memory devices 3231 to 323n are connected to the SSD controller 3210 through a plurality of channels CH1 to CHn. One channel may be connected to one or more nonvolatile memory devices. The nonvolatile memory devices connected to one channel may be connected to the same signal bus and data bus.

The power supply 3240 is configured to provide power PWR inputted through the power connector 3260 into the SSD 3200. The power supply 3240 includes an auxiliary power supply 3241. The auxiliary power supply 3241 is configured to supply power to normally terminate the SSD 3200, when sudden power off occurs. The auxiliary power supply 3241 may include super capacitors capable of storing the power PWR.

The SSD controller 3210 is configured to exchange signals SGL with the host 3100 through the signal connector 3250. Here, the signals SGL may include commands, addresses, data and the like. The signal connector 3250 may include a connector such as PATA (Parallel Advanced Technology Attachment), SATA (Serial Advanced Technology Attachment), SCSI (Small Computer System Interface), or SAS (Serial SCSI), according to the interface method between the host 3100 and the SSD 3200.

FIG. 9 is a block diagram illustrating the SSD controller illustrated in FIG. 8. Referring to FIG. 9, the SSD controller 3210 includes a memory interface 3211, a host interface 3212, an ECC unit 3213, a CPU 3214, and a RAM 3215.

The memory interface 3211 is configured to provide a command and an address to the nonvolatile memory devices 3231 to 323n. Furthermore, the memory interface 3211 is configured to exchange data with the nonvolatile memory devices 3231 to 323n. The memory interface 3211 may scatter data transferred from the buffer memory device 3220 over the respective channels CH1 to CHn, according to the control of the CPU 3214. Furthermore, the memory interface 3211 transfers data read from the nonvolatile memory devices 3231 to 323n to the buffer memory device 3220, according to the control of the CPU 3214.

The host interface 3212 is configured to provide an interface with the SSD 3200 in response to the protocol of the host 3100. For example, the host interface 3212 may be configured to communicate with the host 3100 through one of PATA (Parallel Advanced Technology Attachment), SATA (Serial Advanced Technology Attachment), SCSI (Small Computer System Interface), SAS (Serial SCSI) protocols. Furthermore, the host interface 3212 may perform a disk emulation function of supporting the host 3100 to recognize the SSD 3200 as a hard disk drive (HDD).

The ECC unit 3213 is configured to generate parity bits based on the data transmitted to the nonvolatile memory devices 3231 to 323n. The generated parity bits may be stored in spare areas of the nonvolatile memory devices 3231 to 323n. The ECC unit 3213 is configured to detect an error of data read from the nonvolatile memory devices 3231 to 323n. When the detected error falls within a correction range, the ECC unit 3213 may correct the detected error.

The CPU 3214 is configured to analyze and process a signal SGL inputted from the host 3100. The CPU 3214 controls overall operations of the SSD controller 3210 in response to a request of the host 3100. The CPU 3214 controls the operations of the buffer memory device 3220 and the nonvolatile memory devices 3231 to 323n according to firmware for driving the SSD 3200. The RAM 3215 is used as a working memory device for driving the firmware.

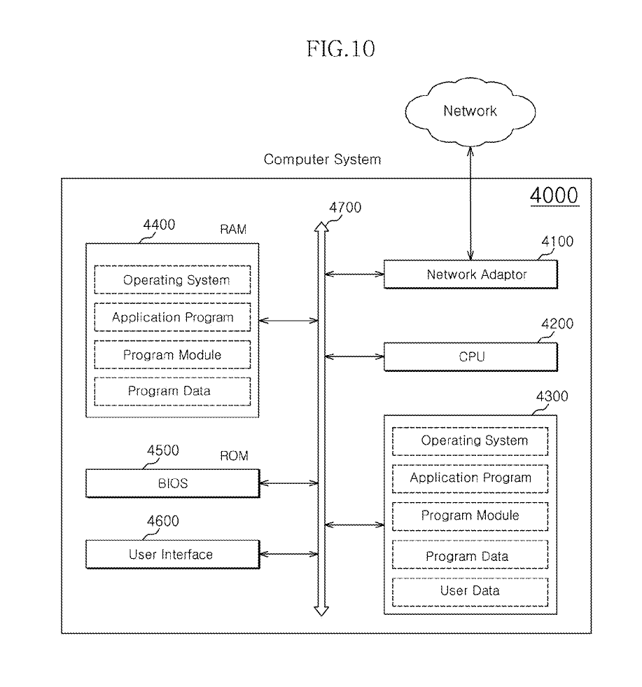

FIG. 10 is a block diagram illustrating a computer system in which a data storage device having the nonvolatile memory device according to an embodiment is mounted. Referring to FIG. 10, the computer system 4000 includes a network adapter 4100, a CPU 4200, a data storage device 4300, a RAM 4400, a ROM 4500, and a user interface 4600, which are electrically connected to the system bus 4700. Here, the data storage device 4300 may include the data storage device 1200 illustrated in FIG. 5 or the SSD 3200 illustrated in FIG. 8.

The network adapter 4100 is configured to provide an interface between the computer system 400 and external networks. The CPU 4200 is configured to perform overall arithmetic operations for driving an operating system or application programs staying in the RAM 4400.

The data storage device 4300 is configured to store overall data required by the computer system 4000. For example, the operating system for driving the computer system 4000, application programs, various program modules, program data, and user data may be stored in the data storage device 4300.

The RAM 4400 may be used as a working memory device of the computer system 4000. During booting, the operating system, application programs, various program modules, which are read from the data storage device 4300, and program data required for driving the programs are loaded into the RAM 4400. The ROM 4500 stores a basic input/output system (BIOS) which is enabled before the operating system is driven. Through the user interface 4600, information exchange is performed between the computer system 4000 and a user.

Although not illustrated in the drawing, the computer system 4000 may further include a battery, application chipsets, a camera image processor (CIP) and the like.

While various embodiments have been described above, it will be understood to those skilled in the art that the embodiments described are by way of example only. Accordingly, the nonvolatile memory device described herein should not be limited based on the described embodiments.

What is claimed is:

1. A nonvolatile memory device comprising:
a plurality of memory cells arranged at a region where word lines and bit lines cross each other;
a control logic configured to control an erase operation for the memory cells; and
a voltage generator configured to apply an erase voltage to the memory cells according to control of the control logic, and collect the applied erase voltage to reuse.

2. The nonvolatile memory device according to claim 1, wherein the control logic controls the erase operation to be performed through a plurality of erase loops, and
the voltage generator gradually increases the erase voltage to apply, whenever the erase loops are repeated.

3. The nonvolatile memory device according to claim 2, wherein the voltage generator collects the erase voltage applied to the memory cells during a previous erase loop, and generates an erase voltage to be applied to the memory cells during a next erase loop, using the collected erase voltage.

4. The nonvolatile memory device according to claim 3, wherein the voltage generator comprises:
a charging unit configured to collect the erase voltage applied to the memory cells during the previous erase loop; and
an erase voltage generation unit configured to generate the erase voltage to be applied to the memory cells during the next erase loop, using the voltage provided from the charging unit.

5. The nonvolatile memory device according to claim 4, wherein, when negative charges stored in a well area having the memory cells formed therein are discharged during the previous erase loop, the charging unit stores the discharged negative charges.

6. The nonvolatile memory device according to claim 4, wherein the charging unit comprises one or more of capacitors.

7. The nonvolatile memory device according to claim 5, wherein the well area comprises a semiconductor substrate having a memory cell array formed therein.

8. The nonvolatile memory device according to claim 1, wherein the memory cells comprise of floating gates and control gates.

9. An operating method of a nonvolatile memory device, comprising the steps of:
applying a first erase voltage to memory cells;
collecting the first erase voltage; and
generating a second erase voltage larger than the first erase voltage, using the collected first erase voltage.

10. The operating method according to claim 9, further comprising the steps of:
determining whether the memory cells which applied the first erase voltage are erased or not; and
when it is determined that the memory cells which applied the first erase voltage are not erased, applying the second erase voltage to the memory cells.

11. The operating method according to claim 9, wherein the step of collecting the first erase voltage comprises the steps of:
discharging negative charges stored in a well area having the memory cells formed therein by applying the first erase voltage; and
storing the negative charges discharged from the well area.

12. A data storage device comprising:
a nonvolatile memory device; and
a controller configured to control the nonvolatile memory device,
wherein the nonvolatile memory device comprises:
a plurality of memory cells arranged at a region where word lines and bit lines cross each other;
a control logic configured to control an erase operation for the memory cells; and
a voltage generator configured to apply an erase voltage to the memory cells according to control of the control logic, and collect the applied erase voltage to reuse.

13. The data storage device according to claim 12, wherein the memory cells are connected to a plurality of word lines and the memory cells comprise of floating gates and control gates.

14. The data storage device according to claim 12, wherein the control logic controls the erase operation to be performed through a plurality of erase loops, and
the voltage generator gradually increases the erase voltage to apply, whenever the erase loops are repeated.

15. The data storage device according to claim 14, wherein the voltage generator collects the erase voltage applied to the memory cells during a previous erase loop, and generates an erase voltage to be applied to the memory cells during a next erase loop, using the collected erase voltage.

16. The data storage device according to claim 15, wherein the voltage generator comprises:
a charging unit configured to collect the erase voltage applied to the memory cells during the previous erase loop; and
an erase voltage generation unit configured to generate the erase voltage to be applied to the memory cells during the next erase loop, using the voltage provided from the charging unit.

17. The data storage device according to claim 16, wherein, when negative charges stored in a well area having the memory cells formed therein are discharged during the previous erase loop, the charging unit stores the discharged negative charges.

18. The nonvolatile memory device according to claim 16, wherein the charging unit comprises one or more of capacitors.

19. The nonvolatile memory device according to claim 12, wherein the nonvolatile memory device and the controller are configured as a memory card.

20. The nonvolatile memory device according to claim 12, wherein the nonvolatile memory device and the controller are configured as a solid state drive (SSD).
